(19) United States
(12) Patent Application Publication
(10) Pub. No.: US 2012/0014091 A1
(43) Pub. Date: Jan. 19, 2012

(54) LED PACKAGE ASSEMBLY AND BACKLIGHT MODULE

(75) Inventors: Chengming He, Guangdong (CN); Jie Ren, Guangdong (CN); Poying Lin, Guangdong (CN)

(73) Assignee: SHENZHEN CHINA STAR OPTOELECTRONICS TECHNOLOGY CO LTD., Shenzhen (CN)

(21) Appl. No.: 12/996,847

(22) PCT Filed: Aug. 12, 2010
(86) PCT No.: PCT/CN2010/075926

§ 371 Date: Dec. 8, 2010

(30) Foreign Application Priority Data
Jul. 14, 2010 (CN) 201010230823.5

(51) Int. Cl. G09F 13/04; H01L 33/60

(52) U.S. Cl. 362/97.1; 257/91; 257/89; 257/E33.061

(57) ABSTRACT

The present invention provides a LED package assembly and a backlight module. The LED package assembly provides three adjacent individual LED package structures separated from each other, for generating red light, green light and blue light, respectively, all of which are mixed with each other to form white light. The foregoing design can ensure that each color light can not be absorbed or scattered by other color fluorescent powders, so that it is advantageous to individually control each color, enhance the luminous efficiency of each color light and expand the color gamut of white light.

### FIELD OF THE INVENTION

The present invention relates to a light emitting diode (LED) package assembly and a backlight module, and more particularly to a LED package assembly capable of individually controlling each color and enhancing the luminous efficiency of each color light and a backlight module having the LED package assembly.

### BACKGROUND OF THE INVENTION

Nowadays, liquid crystal displays (LCDs) have been widely applied to various electronic products, wherein most of the LCDs are backlight type LCDs which are constructed by a LCD panel and a backlight module. The backlight module can be divided into side-light type and direct-light type according to different incidence location of light source, and be used to provide a backlight source to the LCD panel, wherein a backlight source of a direct-light type backlight module structure can be selected from cold cathode fluorescent lamp (CCFL), light emitting diode (LED), electro-luminescence (EL) sheet and etc. Although most of the traditional direct-light type backlight module structures still use CCFL as a backlight source, there are more and more new LCD products which further use LEDs as a backlight source in consideration of various new needs including energy saving, wide color gamut, compactness and etc.

Referring now to FIG. 1A, a traditional light emitting diode (LED) package assembly is illustrated, wherein a LED package assembly 10 comprises: a blue LED chip “B” which can emit blue light after being energized; and a yellow package encapsulant “Y” which includes transparent packaging material and yellow fluorescent powders mixed therein, wherein the yellow package encapsulant “Y” is used to cover and protect the blue LED chip “B”. During blue light emitted from the blue LED chip “B” passes through the yellow package encapsulant “Y”, a portion of the blue light excites the yellow fluorescent powders to generate the yellow light. As a result, the remaining blue light and the excited yellow light commonly emit out of the yellow package encapsulant “Y” and then mixed with each other to form white light.

Referring now to FIG. 1B, another traditional light emitting diode (LED) package assembly is illustrated, wherein a LED package assembly 11 comprises: a blue LED chip “B” which can emit blue light after being energized; a red package encapsulant “R” which includes transparent packaging material and red fluorescent powders mixed therein, wherein the red package encapsulant “R” is used to cover and protect the blue LED chip “B”; and a green package encapsulant “G” which includes transparent packaging material and green fluorescent powders mixed therein, wherein the green package encapsulant “G” is stacked on the red package encapsulant “R”. During blue light emitted from the blue LED chip “B” passes through the red package encapsulant “R”, a portion of the blue light excites the red fluorescent powders to generate the red light, so that the remaining blue light and the excited red light commonly emit into the green package encapsulant “G”. At this time, another portion of the blue light excites the green fluorescent powders to generate the green light. As a result, the remaining blue light and the excited yellow and green light commonly emit out of the green package encapsulant “G” and then mixed with each other to form white light.

Referring now to FIG. 1C, one another traditional light emitting diode (LED) package assembly is illustrated, wherein a LED package assembly 12 comprises: a blue LED chip “B” which can emit blue light after being energized; and a red/green mixed package encapsulant “R+G” which includes transparent packaging material and red and green fluorescent powders mixed therein, wherein the red/green mixed package encapsulant “R+G” is used to cover and protect the blue LED chip “B”. During blue light emitted from the blue LED chip “B” passes through the red/green mixed package encapsulant “R+G”, a portion of the blue light excites the red fluorescent powders to generate the red light, and another portion of the blue light excites the green fluorescent powders to generate the green light. As a result, the remaining blue light and the excited red and green light commonly emit out of the red/green mixed package encapsulant “R+G” and then mixed with each other to form white light.

However, the disadvantage of the LED package assembly 10 of FIG. 1A is that: because the white light mixed by the blue light and the excited yellow light only can show about 70% color gamut, it can not carry out wider color gamut. Furthermore, the disadvantage of the LED package assemblys 11, 12 of FIGS. 1B and 1C is that: a portion of red light will be absorbed or scattered by the red and green fluorescent powders, so that the luminous efficiency of the red light is insufficient.

As a result, it is necessary to provide a LED package assembly to solve the problems existing in the conventional technologies, as described above.

### SUMMARY OF THE INVENTION

A primary object of the present invention is to provide a light emitting diode (LED) package assembly and a backlight module, wherein the LED package assembly provides three adjacent individual LED package structures separated from each other, for generating red light, green light and blue light, respectively, all of which are mixed with each other to form white light. The foregoing design can ensure that each color light can not be absorbed or scattered by other color fluorescent powders, so that it is advantageous to individually control each color, enhance the luminous efficiency of each color light and expand the color gamut of white light.

To achieve the above object, the present invention provides a light emitting diode (LED) package assembly wherein the LED package assembly comprises: a first LED package structure having a blue LED chip and a red package encapsulant, wherein a portion of blue light generated by the blue LED chip excites red fluorescent powders mixed in the red package encapsulant, so as to emit red light; a second LED package structure having a blue LED chip and a green package encapsulant, wherein a portion of blue light generated by the blue LED chip excites green fluorescent powders mixed in the green package encapsulant, so as to emit green light; and a third LED package structure having a blue LED chip and a colorless package encapsulant, wherein the blue LED chip generates blue light; wherein the red light, the green light and the blue light are mixed with each other to form white light.

Furthermore, the present invention provides another light emitting diode (LED) package assembly wherein the LED package assembly comprises: a first LED package structure having an ultraviolet LED chip and a red package encapsulant, wherein a portion of ultraviolet light generated by the ultraviolet LED chip excites red fluorescent powders mixed in the red package encapsulant, so as to emit red light; a second LED package structure having an ultraviolet LED chip and a green package encapsulant, wherein a portion of ultraviolet light generated by the ultraviolet LED chip excites green fluorescent powders mixed in the green package encapsulant, so as to emit green light; and a third LED package structure having an ultraviolet LED chip and a blue package encapsulant, wherein a portion of ultraviolet light generated by the ultraviolet LED chip excites blue fluorescent powders mixed in the blue package encapsulant, so as to emit blue light; wherein the red light, the green light and the blue light are mixed with each other to form white light.

Moreover, the present invention provides one another light emitting diode (LED) package assembly wherein the LED package assembly comprises: a first LED package structure having an ultraviolet LED chip and a red package encapsulant, wherein a portion of ultraviolet light generated by the ultraviolet LED chip excites red fluorescent powders mixed in the red package encapsulant, so as to emit red light; a second LED package structure having an ultraviolet LED chip and a green package encapsulant, wherein a portion of ultraviolet light generated by the ultraviolet LED chip excites green fluorescent powders mixed in the green package encapsulant, so as to emit green light; and a third LED package structure having a blue LED chip and a colorless package encapsulant, wherein the blue LED chip generates blue light; wherein the red light, the green light and the blue light are mixed with each other to form white light.

In one embodiment of the present invention, the LED package assembly is installed in a backlight module and used as a backlight source of the backlight module. In other words, the backlight module comprises a plurality of backlight sources, wherein at least one of the backlight sources has the LED package assembly.

In one embodiment of the present invention, material of the red package encapsulant, the green package encapsulant, the colorless package encapsulant or the blue package encapsulant is transparent silicone (silica gel) or epoxy resin.

In one embodiment of the present invention, the wavelength of the blue light is ranged between 440 and 460 nm; the wavelength of the red light is ranged between 620 and 660 nm; and the wavelength of the green light is ranged between 520 and 570 nm.

In one embodiment of the present invention, the third LED package structure is disposed between the first and second LED package structures.

In one embodiment of the present invention, the third LED package structure is disposed on one side of the first and second LED package structures.

In one embodiment of the present invention, adjacent wall surfaces of the first, second and third LED package structures are coated with a reflective layer, respectively.

### DESCRIPTION OF THE DRAWINGS

FIG. 1A is a schematic view of a traditional LED package assembly;

FIG. 1B is a schematic view of another traditional LED package assembly;

FIG. 1C is a schematic view of one another traditional LED package assembly;

FIG. 2 is a schematic view of a LED package assembly according to a first embodiment of the present invention;

FIG. 3 is a schematic view of a LED package assembly according to a second embodiment of the present invention; and

FIG. 4 is a schematic view of a LED package assembly according to a third embodiment of the present invention.

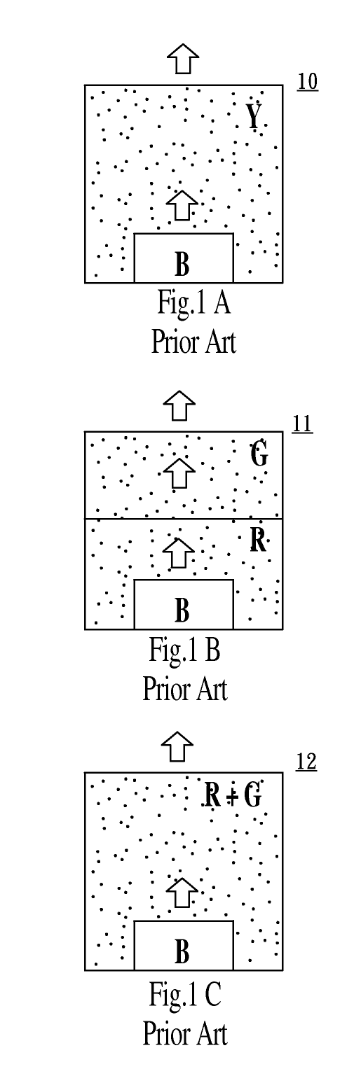

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

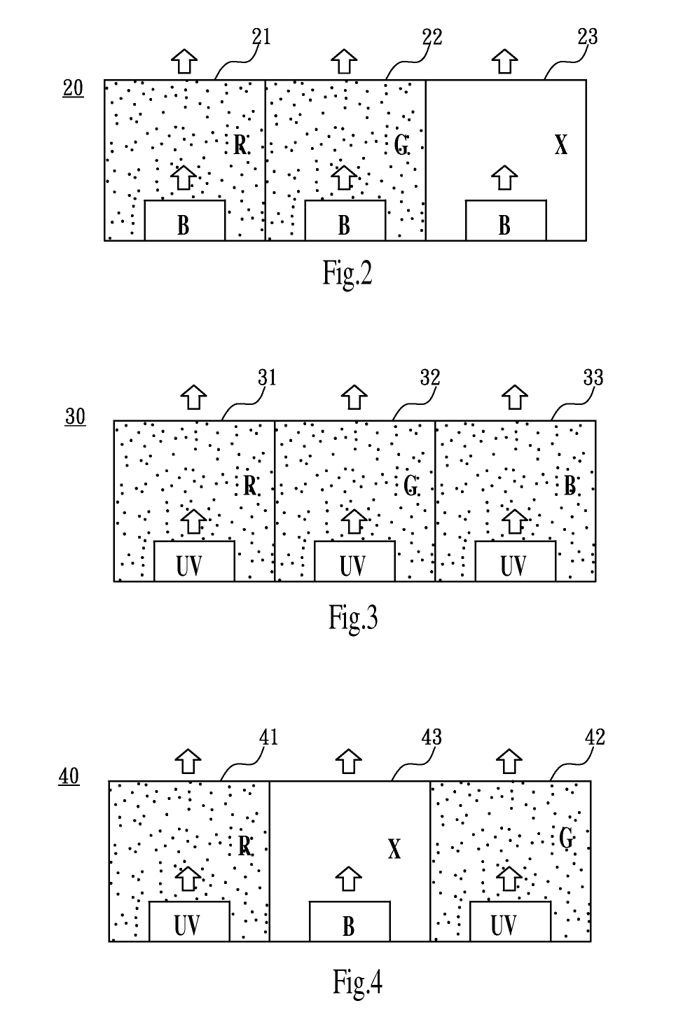

Referring now to FIG. 2, a schematic view of a light emitting diode (LED) package assembly according to a first embodiment of the present invention is illustrated. As shown, a LED package assembly 20 is mainly applied to install in a backlight module (not-shown) and used as backlight sources of the backlight module, wherein the backlight module is particularly a backlight module of liquid crystal display (LCD). In other words, the backlight module comprises a plurality of backlight sources, wherein at least one of the backlight sources has the LED package assembly. In addition, the arrangement and number of the LED package assembly 20 of the present invention in the backlight module are not limited. In the first embodiment of the present invention, the LED package assembly 20 comprises a first LED package structure 21, a second LED package structure 22 and a third LED package structure 23, wherein the third LED package structure 23 can be disposed on one side of the first and second LED package structures 21, 22. But, according to the present invention, the third LED package structure 23 also can be disposed between the first and second LED package structures 21, 22. The first LED package structure 21 is mainly used to generate red light (and a portion of blue light), the second LED package structure 22 is mainly used to generate green light (and a portion of blue light), and the third LED package structure 23 is mainly used to generate blue light, wherein the red light, the green light and the blue light can be mixed with each other to form white light.

Referring still to FIG. 2, the first LED package structure 21 in the preferred embodiment of the present invention has a blue LED chip “B” and a red package encapsulant “R”, wherein the blue LED chip “B” can generate blue light after being energized. Material of the red package encapsulant “R” is preferably transparent silicone (silica gel) or epoxy resin, and evenly mixed with red fluorescent powders. A portion of the blue light generated by the blue LED chip “B” excites red fluorescent powders, so as to emit red light. In addition, the second LED package structure 22 has a blue LED chip “B” and a green package encapsulant “G”, wherein the blue LED chip “B” can generate blue light after being energized. Material of the green package encapsulant “G” is preferably transparent silicone (silica gel) or epoxy resin, and evenly mixed with green fluorescent powders. A portion of the blue light generated by the blue LED chip “B” excites green fluorescent powders, so as to emit green light. Moreover, the third LED package structure 23 has a blue LED chip “B” and a colorless package encapsulant “X”, wherein the blue LED chip “B” can generate blue light after being energized. Material of the colorless package encapsulant “X” is preferably transparent silicone (silica gel) or epoxy resin, and substantially has no any fluorescent powders therein. In the present invention, the first, second and third LED package structure 21, 22, 23 generally can be built on a leadframe or a substrate, and the blue LED chips “B” can be regular type or flip-chip type LED configuration. Besides, in the present invention, the type of the three blue LED chips “B” is not limited. Only if the LED chip is able to emit blue light with the wavelength ranged between 440 and 460 nm, it can be used as the blue LED chip “B” of the present invention. Furthermore, the type of the red fluorescent powders (or the green fluorescent powders) is not limited. Only if the fluorescent powders are able to emit red light with the wavelength ranged between 620 and 660 nm (or green light with the wavelength ranged between 520 and 570 nm), it can be used as the red fluorescent powders (or the green fluorescent powders) of the present invention.

Referring to FIG. 2, when the three blue LED chips “B” of the LED package assembly 20 of the first embodiment of the present invention are energized by an electric current and thus generate blue light, a portion of blue light generated by the blue LED chip “B” of the first LED package structure 21 excites the red fluorescent powders in the red package encapsulant “R”, so as to emit red light and remain some portion of blue light; a portion of blue light generated by the blue LED chip “B” of the second LED package structure 22 excites the green fluorescent powders in the green package encapsulant “G”, so as to emit green light and remain some portion of blue light; and the blue LED chip “B” of the third LED package structure 23 is mainly used to generate blue light, wherein the red light, the green light and the blue light can be mixed with each other to form white light. Especially, because the first, second and third LED package structure 21, 22, 23 generating three primary colors are separately adjacent to each other, the luminous efficiency of red light, green light and blue light generated by each of them will not be affected by each other. In other words, the red light of the first LED package structure 21 will not be absorbed or scattered by the green fluorescent powders or other fluorescent powders; the green light of the second LED package structure 22 will not be absorbed or scattered by the red fluorescent powders or other fluorescent powders; and the blue light of the third LED package structure 23 will not be absorbed or scattered by the red fluorescent powders, the green fluorescent powders or other fluorescent powders. Thus, it is not only helpful to enhance the luminous efficiency of each color light, but also is convenient to individually control each primary color and expand the color gamut of white light. In addition, adjacent wall surfaces of the first, second and third LED package structures 21, 22, 23 can be coated with a reflective layer, respectively, in order to surely prevent the color light of one LED package structure from emitting into another adjacent LED package structure and thus being absorbed or scattered by fluorescent powders of the adjacent LED package structure.

Referring now to FIG. 3, a LED package assembly according to a second embodiment of the present invention is similar to the first embodiment of the present invention, but the difference of the second embodiment is that: the LED package assembly 30 of the second embodiment comprises: a first LED package structure 31, a second LED package structure 32 and a third LED package structure 33, wherein the first LED package structure 31 has an ultraviolet LED chip “UV” and a red package encapsulant “R”. The red package encapsulant “R” is mixed with red fluorescent powders, and a portion of ultraviolet light generated by the ultraviolet LED chip “UV” can excite the red fluorescent powders, so as to emit red light. The second LED package structure 32 has an ultraviolet LED chip “UV” and a green package encapsulant “G”. The green package encapsulant “G” is mixed with green fluorescent powders, and a portion of ultraviolet light generated by the ultraviolet LED chip “UV” can excite the green fluorescent powders, so as to emit green light. The third LED package structure 33 has an ultraviolet LED chip “UV” and a blue package encapsulant “B”. The blue package encapsulant “B” is mixed with blue fluorescent powders, and a portion of ultraviolet light generated by the ultraviolet LED chip “UV” can excite the blue fluorescent powders, so as to emit blue light; wherein the red light, the green light and the blue light are mixed with each other to form white light. Similarly, because the first, second and third LED package structure 31, 32, 33 generating three primary colors are separately adjacent to each other, the luminous efficiency of red light, green light and blue light generated by each of them will not be affected by each other. In other words, the red light of the first LED package structure 31 will not be absorbed or scattered by the green fluorescent powders, the blue fluorescent powders or other fluorescent powders; the green light of the second LED package structure 32 will not be absorbed or scattered by the red fluorescent powders, the blue fluorescent powders or other fluorescent powders; and the blue light of the third LED package structure 33 will not be absorbed or scattered by the red fluorescent powders, the green fluorescent powders or other fluorescent powders. Thus, it is not only helpful to enhance the luminous efficiency of each color light, but also is convenient to individually control each primary color and expand the color gamut of white light. In the embodiment, the third LED package structure 33 can be disposed on one side of the first and second LED package structures 31, 32. But, according to the present invention, the third LED package structure 33 also can be disposed between the first and second LED package structures 31, 32.

Referring now to FIG. 4, a LED package assembly according to a third embodiment of the present invention is similar to the first and second embodiments of the present invention, but the difference of the third embodiment is that: the LED package assembly 40 of the third embodiment comprises: a first LED package structure 41, a second LED package structure 42 and a third LED package structure 43, wherein the first LED package structure 41 has an ultraviolet LED chip “UV” and a red package encapsulant “R”. The red package encapsulant “R” is mixed with red fluorescent powders, and a portion of ultraviolet light generated by the ultraviolet LED chip “UV” can excite the red fluorescent powders, so as to emit red light. The second LED package structure 42 has an ultraviolet LED chip “UV” and a green package encapsulant “G”. The green package encapsulant “G” is mixed with green fluorescent powders, and a portion of ultraviolet light generated by the ultraviolet LED chip “UV” can excite the green fluorescent powders, so as to emit green light. The third LED package structure 43 has a blue LED chip “B” and a colorless package encapsulant “X”. The blue LED chip “B” can emit blue light; wherein the red light, the green light and the blue light are mixed with each other to form white light. Similarly, because the first, second and third LED package structure 41, 42, 43 generating three primary colors are separately adjacent to each other, the luminous efficiency of red light, green light and blue light generated by each of them will not be affected by each other. In other words, the red light of the first LED package structure 41 will not be absorbed or scattered by the green fluorescent powders or other fluorescent powders; the green light of the second LED package structure 42 will not be absorbed or scattered by the red fluorescent powders or other fluorescent powders; and the blue light of the third LED package structure 43 will not be absorbed or scattered by the red fluorescent powders, the green fluorescent powders or other fluorescent powders. Thus, it is not only helpful to enhance the luminous efficiency of each color light, but also is convenient to individually control each primary color and expand the color gamut of white light. In the embodiment, the third LED package structure 43 can be disposed between the first and second LED package structures 41, 42. But, according to the present invention, the third LED package structure 43 also can be disposed on one side of the first and second LED package structures 41, 42.

As described above, in comparison with the traditional white LED package assembly which can not carry out wider color gamut or the luminous efficiency of a portion of color light is insufficient, the LED package assembly 20, 30, 40 of the present invention as shown in FIGS. 2 to 4 can provide three adjacent individual LED package structures 21-23, 31-33, 41-43 separated from each other, for generating red light, green light and blue light, respectively, all of which are mixed with each other to form white light, and can ensure that each color light can not be absorbed or scattered by other color fluorescent powders, so that it is surely advantageous to individually control each color, enhance the luminous efficiency of each color light and expand the color gamut of white light.

The present invention has been described with a preferred embodiment thereof and it is understood that many changes and modifications to the described embodiment can be carried out without departing from the scope and the spirit of the invention that is intended to be limited only by the appended claims.

1. A LED package assembly, comprising a first LED package structure, a second LED package structure and a third LED package structure, characterized in that:
the first LED package structure has a blue LED chip and a red package encapsulant, wherein a portion of blue light generated by the blue LED chip excites red fluorescent powders mixed in the red package encapsulant, so as to emit red light;
the second LED package structure has a blue LED chip and a green package encapsulant, wherein a portion of blue light generated by the blue LED chip excites green fluorescent powders mixed in the green package encapsulant, so as to emit green light; and
the third LED package structure has a blue LED chip and a colorless package encapsulant, wherein the blue LED chip generates blue light;
wherein the red light, the green light and the blue light are mixed with each other to form white light.

2. The LED package assembly according to claim 1, characterized in that: the third LED package structure is disposed on one side of the first and second LED package structures; or the third LED package structure is disposed between the first and second LED package structures.

3. The LED package assembly according to claim 1, characterized in that: adjacent wall surfaces of the first, second and third LED package structures are coated with a reflective layer, respectively.

4. The LED package assembly according to claim 2, characterized in that: adjacent wall surfaces of the first, second and third LED package structures are coated with a reflective layer, respectively.

5. A backlight module, characterized in that: the backlight module comprises a plurality of backlight sources, wherein at least one of the backlight sources has the LED package assembly according to claim 1.

6. A LED package assembly, comprising a first LED package structure, a second LED package structure and a third LED package structure, characterized in that:
the first LED package structure has an ultraviolet LED chip and a red package encapsulant, wherein a portion of ultraviolet light generated by the ultraviolet LED chip excites red fluorescent powders mixed in the red package encapsulant, so as to emit red light;
the second LED package structure has an ultraviolet LED chip and a green package encapsulant, wherein a portion of ultraviolet light generated by the ultraviolet LED chip excites green fluorescent powders mixed in the green package encapsulant, so as to emit green light; and
the third LED package structure has an ultraviolet LED chip and a blue package encapsulant, wherein a portion of ultraviolet light generated by the ultraviolet LED chip excites blue fluorescent powders mixed in the blue package encapsulant, so as to emit blue light;
wherein the red light, the green light and the blue light are mixed with each other to form white light.

7. The LED package assembly according to claim 6, characterized in that: the third LED package structure is disposed on one side of the first and second LED package structures; or the third LED package structure is disposed between the first and second LED package structures.

8. The LED package assembly according to claim 6, characterized in that: adjacent wall surfaces of the first, second and third LED package structures are coated with a reflective layer, respectively.

9. The LED package assembly according to claim 7, characterized in that: adjacent wall surfaces of the first, second and third LED package structures are coated with a reflective layer, respectively.

10. A backlight module, characterized in that: the backlight module comprises a plurality of backlight sources, wherein at least one of the backlight sources has the LED package assembly according to claim 6.

11. A LED package assembly, comprising a first LED package structure, a second LED package structure and a third LED package structure, characterized in that:
the first LED package structure has an ultraviolet LED chip and a red package encapsulant, wherein a portion of ultraviolet light generated by the ultraviolet LED chip excites red fluorescent powders mixed in the red package encapsulant, so as to emit red light;
the second LED package structure has an ultraviolet LED chip and a green package encapsulant, wherein a portion of ultraviolet light generated by the ultraviolet LED chip excites green fluorescent powders mixed in the green package encapsulant, so as to emit green light; and
the third LED package structure has a blue LED chip and a colorless package encapsulant, wherein the blue LED chip generates blue light;
wherein the red light, the green light and the blue light are mixed with each other to form white light.

12. The LED package assembly according to claim 11, characterized in that: the third LED package structure is disposed on one side of the first and second LED package structures; or the third LED package structure is disposed between the first and second LED package structures.

13. The LED package assembly according to claim 11, characterized in that: adjacent wall surfaces of the first, second and third LED package structures are coated with a reflective layer, respectively.

14. The LED package assembly according to claim 12, characterized in that: adjacent wall surfaces of the first, second and third LED package structures are coated with a reflective layer, respectively.

15. A backlight module, characterized in that: the backlight module comprises a plurality of backlight sources, wherein at least one of the backlight sources has the LED package assembly according to claim 11.
